(19) United States
(12) Patent Application Publication
(10) Pub. No.: US 2021/0391229 A1
(43) Pub. Date: Dec. 16, 2021

(54) POWER ELECTRONIC CIRCUIT DEVICE WITH A PRESSURE DEVICE

(71) Applicant: SEMIKRON ELEKTRONIK GMBH & CO. KG, Nuremberg (DE)

(72) Inventors: Markus Düsel, Hallerndorf (DE); Harald Kobolla, Seukendorf (DE); Manuel Noderer, Nuremberg (DE); Alexander Wehner, Nuremberg (DE)

(73) Assignee: SEMIKRON ELEKTRONIK GMBH & CO. KG, Nuremberg (DE)

(21) Appl. No.: 17/336,150

(22) Filed: Jun. 1, 2021

(30) Foreign Application Priority Data
Jun. 16, 2020 (DE) 10 2020 115 831.9

(51) Int. Cl. H01L 23/16; H01L 23/498; H01L 23/00; H01L 23/043

(52) U.S. Cl. CPC H01L 23/16; H01L 23/49838; H01L 2224/40227; H01L 23/043; H01L 24/40

(57) ABSTRACT

A power electronic circuit device has a substrate, with multiple conductive tracks, and a power semiconductor component on these conductive tracks has a connection device with a metal sheet which electrically connects a contact pad of the power semiconductor component to a contact pad of a further power semiconductor component or a conductive track, and has a pressure device. The connection device includes a contact section for connection to an assigned contact pad and a connecting section arranged between the two contact sections. The pressure device includes a two-dimensional resilient pressure element that comprises pressure element sections, and first pressure element sections press with a first pressure surface section onto a contact section and second pressure element section presses with a second pressure surface section press onto the connecting section.

### CROSS REFERENCE TO RELATED APPLICATIONS

This application relates to and claims priority to DE 10 2020 115 831.9 filed Jun. 16, 2020, the entire contents of which are incorporated herein by reference.

### FIGURE SELECTED FOR PUBLICATION

FIG. 5

### BACKGROUND OF THE INVENTION

### Field of the Invention

The invention relates to a power electronic circuit device having a substrate comprising a multiplicity of conductive tracks, having a power semiconductor component arranged on these conductive tracks, the contact pad of which facing away from the substrate defines a normal direction, having a connection device with a metal sheet, which electrically conductively connects the contact pad of the power semiconductor component to a further contact pad of a further power semiconductor component or a conductive track, and having a pressure device.

### Description of the Related Art

DE 10 2016 123 697 A1 discloses a pressure device for a power electronic circuit device, which is configured with a two-dimensionally extended rigid base body and a resiliently deformable elastomer body, wherein the base body and the elastomer body are reversibly connected to one another with a force or form fit, and wherein the elastomer body comprises a multiplicity of pressure bodies. Furthermore, two power electronic circuit devices and arrangement having such a pressure device are proposed.

DE 10 2017 126 716 A1 discloses, as also represented in principle in FIG. 7, an arrangement and a power semiconductor module therefor, the latter being formed with a circuit device that comprises a substrate, a connection device and terminal devices, preferably load and auxiliary terminal devices, and with a pressure device arranged movably in the normal direction of the substrate, wherein the substrate comprises conductive tracks electrically insulated from one another, wherein a power semiconductor component is arranged on one conductive track and is electrically conductively connected thereto, wherein the circuit device is internally connected according to its circuitry by means of the connection device, wherein the pressure device comprises a rigid base body, a resilient pressure body and a spring body or a multiplicity of spring bodies, wherein the resilient pressure body protrudes from the base body onto the substrate in the normal direction of the substrate, and wherein the spring body is braced on a support that is immobile relative to the substrate and presses the pressure body in the normal direction of the substrate in the direction towards the substrate and therefore indirectly or directly against the substrate and therefore also onto the circuit device.

### ASPECTS AND SUMMARY OF THE INVENTION

With knowledge of the prior art, the object of the invention is to further improve the pressure device and, in particular, to induce the pressure on the substrate together with the power semiconductor components in a more controlled way.

This object is achieved according to the invention by a power electronic circuit device having a substrate comprising a multiplicity of conductive tracks, having a power semiconductor component arranged on these conductive tracks, the contact pad of which facing away from the substrate defines a normal direction, having a connection device with a metal sheet, which electrically conductively connects the contact pad of the power semiconductor component to a further contact pad of a further power semiconductor component or a conductive track, and having a pressure device, wherein the connection device respectively comprises a contact section for connection to an assigned contact pad and a connecting section which is arranged between the two contact sections, wherein the pressure device comprises a two-dimensional resilient pressure element that comprises pressure element sections, wherein the first pressure element sections press with a respective first pressure surface section onto an assigned contact section and the second pressure element section presses with a second pressure surface section two a lower section or the entire connecting section.

Here, the connecting section may have a preferably arched profile and, in this case, preferably have a highest point placed in the normal direction, the level of which lies above the two neighboring contact sections.

It is particularly preferred for the connecting section to be configured as a sheet stack alternately having a metal sheet and an insulation sheet.

It is advantageous for one, preferably all, of the first pressure element sections, to have a thickness of from 0.5 mm to 15 mm and preferably between 2 mm and 8 mm.

It is furthermore advantageous for the respective first pressure surface section to be configured in a planar fashion, and for the second pressure surface section to have a curved surface contour, preferably matched to the connecting section. In this way, the respective pressures surface sections can bear on the assigned sections of the connection device and exert pressure there in a planar fashion.

It is particularly advantageous for the pressure element to comprise a first material section consisting of a first resilient material and a second material section consisting of a second resilient material. In this case, the first resilient material may be formed from the material group of elastomers, in particular that of silicone rubbers, with a Shore-A hardness of between 30 and 90 and in particular between 60 and 70, and the second resilient material may likewise be formed from this material group, respectively with a second Shore-A hardness, which is 5%, in particular 10%, less than the first Shore-A hardness, or the second resilient material may be formed from the material group of plastic foams, in particular from silicone foam with a compression force according to ASTM D1056 of between 25 kPa and 250 kPa, and in particular between 100 kPa and 150 kPa.

In particular applications, it may also be advantageous for the first pressure element section to be identical to the first material section and for the second pressure element section to be identical to the second material section. As an alternative, the first material section may be arranged inside the first pressure element section and may preferably have a volume smaller than it by at most 30%. As an alternative, the second material section may be arranged inside the second pressure element section and may preferably have a volume smaller than it by at most 30%. As an alternative, the first material section may comprise first depressions, in which the second material section is arranged, in the region of the second pressure element section. Furthermore, as an alternative, the second material section may comprise second depressions, in which the first material section is arranged, in the region of the first pressure element section.

It is furthermore preferred for the pressure element to be arranged in a depression of a pressure frame, which preferably comprises a metal stabilization element.

By the configuration according to the invention of the power electronic circuit device, and in this case particularly of the pressure device, pressure may be exerted more flexibly onto the respective power semiconductor component, and at the same time also onto regions of the connection device next to the contact pad of the power semiconductor component, and also next to the power semiconductor component itself, in a defined way.

Of course, unless excluded explicitly or per se or conflicting with the concept of the invention, the features respectively mentioned in the singular, in particular the power semiconductor component, may be present in the plural in the circuit device according to the invention.

It is to be understood that the various configurations of the invention may be implemented individually or in any desired combinations in order to achieve improvements. In particular, the features mentioned and explained above and below may be used not only in the combinations specified but also in other combinations or separately, without departing from the scope of the present invention.

The above and other aspects, features, objects, and advantages of the present invention will become apparent from the following description read in conjunction with the accompanying drawings, in which like reference numerals designate the same elements.

### BRIEF DESCRIPTION OF THE DRAWINGS

FIG. 1 shows a first configuration of a power electronic circuit device according to the invention in a lateral exploded representation.

FIGS. 2A, 2B, 2C, and 2D show the contact and connecting sections of various configurations of pressure elements.

FIGS. 3A, 2B, 3C, and 3D show first and second material sections of various arrangements and configurations of pressure elements.

FIGS. 4A, 4B, and 4C show further first and second material sections of various arrangements and configurations of pressure elements.

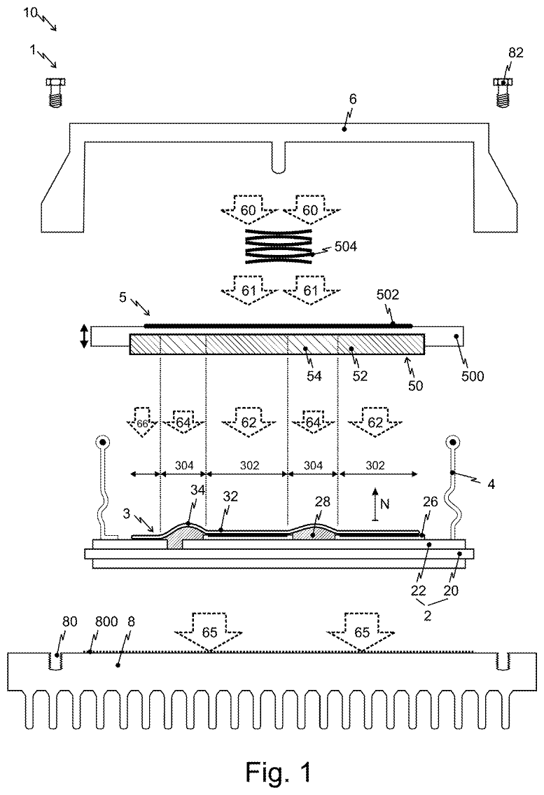

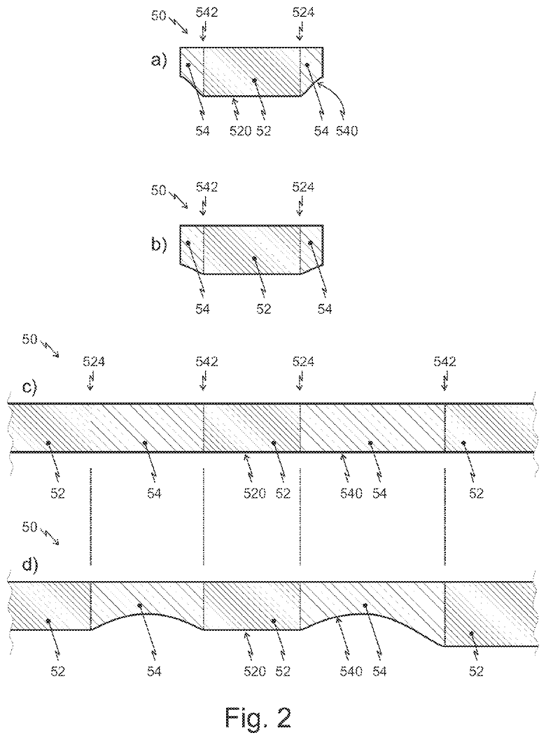

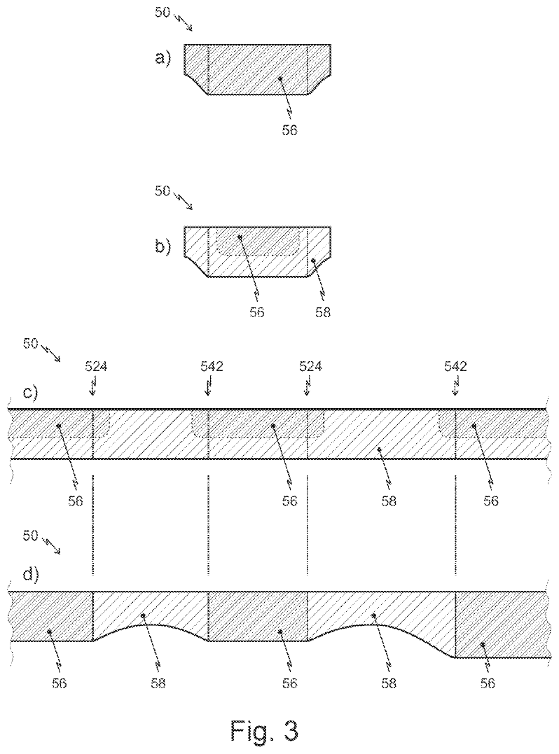

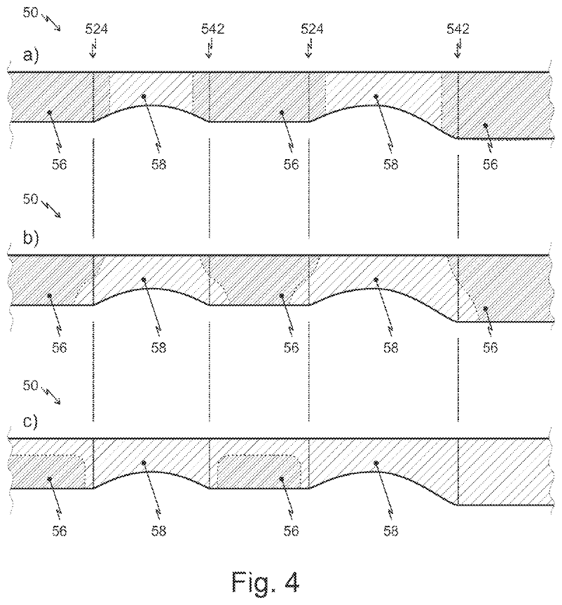

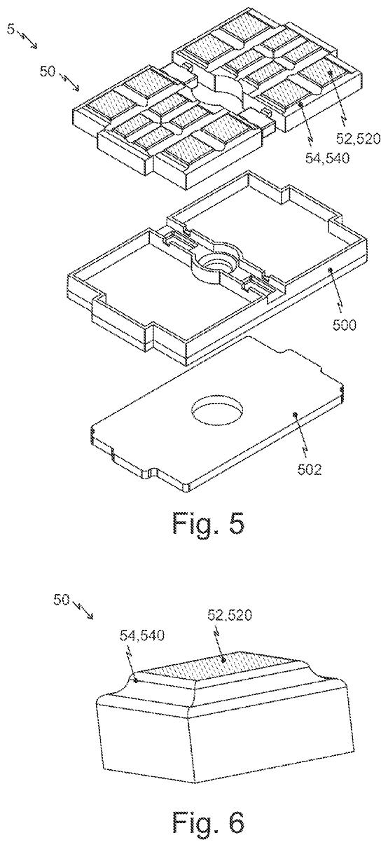

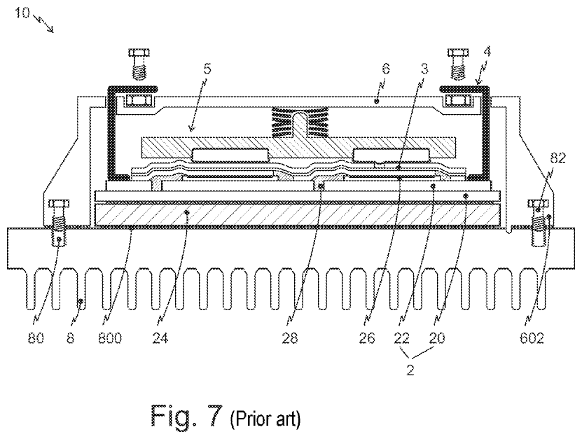

FIG. 5 shows a three-dimensional exploded representation of a pressure device.

FIG. 6 shows a three-dimensional representation of an individual pressure element.

FIG. 7 shows a power electronic circuit device according to the prior art as already described above.

### DETAILED DESCRIPTION OF THE PREFERRED EMBODIMENTS

Reference will now be made in detail to embodiments of the invention. Wherever possible, same or similar reference numerals are used in the drawings and the description to refer to the same or like parts or steps. The drawings are in simplified form and are not to precise scale. The word ‘couple’ and similar terms do not necessarily denote direct and immediate connections, but also include connections through intermediate elements or devices. For purposes of convenience and clarity only, directional (up/down, etc.) or motional (forward/back, etc.) terms may be used with respect to the drawings. These and similar directional terms should not be construed to limit the scope in any manner. It will also be understood that other embodiments may be utilized without departing from the scope of the present invention, and that the detailed description is not to be taken in a limiting sense, and that elements may be differently positioned, or otherwise noted as in the appended claims without requirements of the written description being required thereto.

FIG. 1 shows, in a lateral exploded representation, a first configuration of a power electronic circuit device 1 according to the invention as part of a power semiconductor module 10 arranged on a cooling device 8, which is configured here without restriction of generality as an air-cooling device.

The power electronic circuit device 1 comprises a power electronic substrate 2 which is conventional in the art. The latter comprises an insulator body 20 and a multiplicity of conductive tracks 22 arranged thereon. Here, two power semiconductor components 26 are arranged on one of these conductive tracks 22. These power semiconductor components 26 comprise a contact pad for electrical contacting on their surface facing away from the substrate 2. This contact pad is assigned a normal direction N. The power electronic substrate 2 is arranged on a surface of the cooling device 8, a thermally conductive paste 800 also being arranged between the substrate 2 and the surface.

Furthermore, represented is a connection device 3, which is configured here as a simple metal sheet but may likewise also be configured as a shaped metal body or in particular as a sheet stack, which is conventional in the art, alternately having a metal sheet and an insulation sheet. This connection device 3 comprises contact sections 32 with a width 302, which are in electrically conductive contact with assigned contact pads of the respective power semiconductor component 26. These contact sections 32 are respectively followed by at least one connecting section 34 with a width 304, which forms the further electrical connection of the power semiconductor component 26 to a further power semiconductor component 26 or to a conductive track 22 of the substrate 2.

The connecting section 34 here respectively has an arched profile, which as considered in the normal direction N has a highest point whose level is higher than the level of the neighboring contact section 32. For example, the connection device 3 has a maximum thickness of 700 μm. In this case, the highest point on the surface of the connection device facing away from the substrate 2 is 500 μm higher than the surface, facing away from the substrate 2 of the neighboring contact section 32.

As is conventional in the art, an insulator compound 28, for example a silicone rubber, is arranged below the connecting section 34 and filling the volume formed there. Furthermore, represented are contact elements 4 for external electrical connection of the circuit device 1.

A pressure device 5 here comprises three constituent parts, a pressure body 500, which has a recess, in which a pressure element 50 is arranged, on its main side facing towards the substrate 2. On its opposite main side, the pressure body 500 has a further recess, in which a two-dimensional metal body 502, cf. also FIG. 5, for stiffening and stabilization is arranged.

The pressure body 500 comprises first pressure element sections 52, explained in more detail below, which press onto contact sections 32 of the connection device 3, and second pressure element sections 54, which press onto connecting sections 34 of the connection device 3.

For the pressure application required therefor onto the pressure device 5, the power semiconductor module 10 comprises a housing 6, which may also be configured as a partial housing. This housing 6 is arranged on the cooling device 8 by means of fastening devices 80, 82, here by means of a screw connection. The cooling device 8 in this case acts as a counter-bearing, by which the induction of pressure onto the pressure device is made possible. The pressure of the housing 6 is induced by means of a spring element 504, here a stack of cup springs, onto the pressure device 5. The pressure element sections 52, 54 of the pressure element 50 forward the pressure onto the connection device 3, so that the substrate 2 is finally pressed onto the surface of the cooling device 8. The arrows 60, 61, 62, 64, 65, 66 represent the pressure respectively induced.

FIGS. 2A, 2B, 2C, and 2C show the first and second pressure element sections 52, 54 of various configurations of pressure elements 50, respectively without pressure application. FIG. 2A, and in a three-dimensional view also FIG. 6, in this case show a pressure element 50 which is formed as an individual pressure element and is configured and intended to press with its first pressure element section 52 onto a contact section 32 of a connection device 3. The second pressure element section 54, arranged extending around the first pressure element section 52, is configured and intended to press onto a subsection, directly adjacent to the contact section 32 and here likewise extending around, of a connecting section 34 of the connection device 3.

The first pressure surface section 520, facing towards the connection device, of the first pressure element section 52 is configured in a planar fashion here since the assigned contact section 32 of the connection device 3 is likewise configured in a planar fashion. The second pressure element section 54 has a contour of its second pressure surface section 540 that follows on continuously from the pressure surface section 520 of the first pressure element 52 and substantially follows the profile of the connection device 3.

FIG. 2B shows an alternative configuration of an individual pressure element 50 with a shallower profile of the surface contour of the second pressure element section 54.

FIG. 2C shows a pressure element 50 which is configured as a multiple pressure element and in the state without pressure application has two mutually parallel surfaces. This pressure element 50 therefore comprises a multiplicity of first and second pressure element sections 52, 54. The boundaries 524, 542 between the first and second pressure element sections 52, 54 are virtual functional boundaries , which are defined by the function but not necessarily by structural properties of the pressure element 50.

FIG. 2D shows a further configuration of a multiple pressure element, in which the pressure surface section 540, facing towards the connection device 3, of the second pressure element section 54 has an arched profile that essentially follows that of the connecting sections 34 of the connection device 3, cf. FIG. 1. Furthermore, the boundaries 524, 542 between the pressure element sections are vertical.

FIGS. 3B, 3C, and 3D, with the exception of FIG. 3A, shows various arrangements and configurations of pressure elements 50 having first and second material sections 56, 58. These first and second material sections 56, 58 are structurally different sections, preferably configured by different properties, in particular compression properties and resilience properties. The first and second material sections 56, 58 may furthermore differ by different material properties.

FIG. 3A shows an individual pressure element 50 formed of only a first material section 56, although with a first and a second pressure element section 52, 54, as represented in FIG. 2A.

FIG. 3B shows an individual pressure element 50 having a first and a second pressure element section 52, 54, here with a first material section 56 being arranged in the shape of a well, and starting from a surface inside a second material section, in the first pressure element section 52. This first material section may alternatively be formed starting from the surface facing towards or away from the connection device. It may (not represented here) also be formed as a buried second material layer.

FIG. 3C shows a multiple pressure element, as already described in relation to FIG. 2C, comprising a multiplicity of first and second pressure element sections 52, 54, here with a first material section 56 being arranged in the first pressure element section 52, and extending laterally beyond it, in the shape of a well and starting from a surface inside a second material section. The variants described in relation to FIG. 2B are of course likewise possible here.

FIG. 3D shows a multiple pressure element as already described in relation to FIG. 2D and also represented in FIG. 5, the first pressure element section 52 here coinciding spatially with the first material section 56. The same also applies of course for the second pressure element section 54 and the second material section 58.

FIGS. 4A, 4B, and 4C show further first and second material sections 56, 58 of various arrangements and configurations of pressure elements 50, which respectively have a geometrical shape as described in relation to FIG. 2D.

FIG. 4A shows a multiple pressure element similar to the one according to FIG. 3D, although here the boundaries between the first and second material sections 56, 58 are shifted perpendicularly to the normal direction N from the first pressure element section 52 into the second pressure element section 54. The region of the first material section 56 is therefore larger than that of the second pressure element section 54.

FIG. 4B shows a multiple pressure element in which the width of the second material section 58 increases constantly from the surface facing towards the connection device to the surface facing away.

FIG. 4C shows a multiple pressure element having zones of the second material section 58 that are arranged in the shape of a well fully inside the first pressure element section 52. These second material sections 58 are arranged on the side of the pressure element 50 facing towards the connection device 3.

For all material sections 56, 58 described in the scope of FIGS. 3A-3D and 4A-4C, it is particularly preferred for the first material section 56 to be formed from a first resilient material and for a second material section 58 to be formed from a second resilient material. In the scope of these examples, without restriction of generality, both resilient materials are silicone rubbers. In this case, the first resilient material has a first Shore-A hardness of 65 while the second resilient material has a second Shore-A hardness of 60.

FIG. 5 shows, cf. also FIG. 1, a three-dimensional exploded representation of a pressure device 5 having a pressure body 500 that comprises recesses on both main sides. On the main side facing away from the connection device 3, a metal stabilization element 502, which is furthermore used for homogeneous pressure distribution, is arranged in the recess there. Multiple pressure elements, which correspond in principle to those according to FIG. 3D, are respectively arranged in two recesses of the main side facing towards the connecting element 3.

FIG. 6 shows a three-dimensional representation of an individual pressure element 50. Such a pressure element 50 has, for example, a thickness of 3 mm and an edge length of 6 mm.

FIG. 7 shows, as already described above, a power electronic circuit device according to the prior art, arranged in a power semiconductor module 10 having a base plate 24 that is mounted on a cooling device 8.

It should be noted at this point that features from different exemplary embodiments of the invention can of course be combined with one another as desired, provided that the features are not mutually exclusive, without departing from the scope of the invention.

Also, the inventors intend that only those claims which use the specific and exact phrase “means for” are intended to be interpreted under 35 USC 122, sixth paragraph. The structure herein is noted and well supported in the entire disclosure. Moreover, no limitations from the specification are intended to be read into any claims, unless those limitations are expressly included in the claims.

Having described at least one of the preferred embodiments of the present invention with reference to the accompanying drawings, it will be apparent to those skills that the invention is not limited to those precise embodiments, and that various modifications and variations can be made in the presently disclosed system without departing from the scope or spirit of the invention. Thus, it is intended that the present disclosure cover modifications and variations of this disclosure provided they come within the scope of the appended claims and their equivalents.

What is claimed is:

1. A power electronic circuit device (1) having a substrate (2), comprising:
a plurality of conductive tracks (22);
a power semiconductor component 26 arranged on each said conductive track of said plurality of conductive tracks (22);
each said power semiconductor component including a contact pad that is facing away from the substrate defines a normal direction N;
each said power semiconductor component (26) having a connection device (3) with a metal sheet which electrically conductively connects each respective said contact pad of the power semiconductor component to one of a further subsequent said contact pad of a further power semiconductor component or one of said conductive track;
each said power semiconductor component having a pressure device (5);
wherein the connection device 3 respectively further comprises:
a contact section (32) for connection to an assigned contact pad and a connecting section (34) which is arranged between the two respective contact sections (32); and
wherein the pressure device (5) comprises a two-dimensional resilient pressure element (50) that further comprises:
respective first and a second pressure element sections (52), (54), wherein the first pressure element sections (52) press with a respective first pressure surface section (520) onto an assigned contact section and the second pressure element section (54) presses with a second pressure surface section (540) onto one of a lower section (36) and the entire connecting section (34).

2. The power electronic circuit device (1), according to claim 1, wherein:
the connecting section has an arched profile and has a highest point placed in the normal direction N; and
the level of the highest point lies above two respective neighboring contact sections.

3. The power electronic circuit device (1), according to claim 3, wherein:
the connecting device is configured as a sheet stack alternately having a metal sheet and an insulation sheet.

4. The power electronic circuit device (1), according to claim 3, wherein:
at least one of the first pressure element sections (52), has a thickness of from 0.5 mm to 15 mm.

5. The power electronic circuit device (1), according to claim 4, wherein:
the respective first pressure surface section (520) is configured in a planar fashion; and
the second pressure surface section (540) has a curved surface contour matched to the connecting section (34).

6. The power electronic circuit device (1), according to claim 5, wherein:
the pressure element (50) further comprises:
a first material section (56) consisting of a first resilient material; and
a second material section (58) consisting of a second resilient material.

7. The power electronic circuit device (1), according to claim 6, wherein:
the first resilient material is formed from the group of elastomers including a silicone rubber, with a first Shore-A hardness of between 30 and 90; and
the second resilient material is formed from one of:
(a) the group of elastomers including silicone rubber, with a second Shore-A hardness, which is 5% or more less than the first Shore-A hardness; and
(b) the group of plastic foams including a silicone foam, with a compression force according to ASTM D1056 of between 25 kPa and 250 kPa.

8. The power electronic circuit device (1), according to claim 7, wherein:
the first pressure element section (52) is identical to the first material section (56) and the second pressure element section (54) is identical to the second material section (58).

9. The power electronic circuit device (1), according to claim 6, wherein:
the first material section (56) is arranged inside the first pressure element section (52) and has a volume smaller than the first pressure element (52) by at most 30%.

10. The power electronic circuit device (1), according to claim 9, wherein:
the second material section (58) is arranged inside the second pressure element section (54) and has a volume smaller than the second pressure element section (54) by at most 30%.

11. The power electronic circuit device (1), according to claim 6, wherein:
the first material section (56) comprises first depressions, in which the second material section (58) is arranged, in the region proximate the second pressure element section (54).

12. The power electronic circuit device (1), according to claim 11, wherein:
the second material section (58) comprises second depressions, in which the first material section (56) is arranged, in the region proximate the first pressure element section (52).

13. The power electronic circuit device (1), according to claim 8, wherein:
the pressure element is arranged in a depression of a pressure frame; and
said pressure frame comprises a metal stabilization element.
